(19) United States
(12) Patent Application Publication
(10) Pub. No.: US 2005/0269709 A1
(43) Pub. Date: Dec. 8, 2005

(54) Interconnect structure including tungsten nitride and a method of manufacture therefor

(75) Inventors: Sailesh Merchant, Breinigsville, PA (US); Arun Nanda, Singapore (SG); Nace Rossi, Singapore (SG)

Correspondence Address: HITT GAINES, PC;AGERE SYSTEMS INC., PO BOX 832570, RICHARDSON, TX, 75083, US

(73) Assignee: Agere Systems Inc., Allentown, PA (US)

(21) Appl. No.: 10/860,621

(22) Filed: Jun. 3, 2004

(51) Int. Cl. H01L 21/44

(52) U.S. Cl. 257/774

(57) ABSTRACT

The present invention provides an interconnect structure, a method of manufacture therefor, and an integrated circuit including the same. The interconnect structure, among other elements, may include a tungsten nitride layer located within an opening in a dielectric layer, and a conductive plug located over the tungsten nitride layer and within the opening. Thus, in certain embodiments the present invention is free of a titanium/titanium nitride layer, and any defects associated with those layers.

### TECHNICAL FIELD OF THE INVENTION

The present invention is directed, in general, to an interconnect structure and, more specifically, to an interconnect structure including tungsten nitride, a method of manufacture therefor and an integrated circuit including the same.

### BACKGROUND OF THE INVENTION

Devices in the semiconductor industry continue to advance toward higher performance, while maintaining or even lowering their cost of manufacture. Micro-miniaturization of semiconductor devices has resulted in higher performance devices through increases in transistor speed and in the number of devices incorporated in a chip. However, this trend has also increased yield and reliability failures.

As contact or via openings decrease in size, the aspect ratio, or the ratio of the depth of the opening to the diameter of the opening, also increases. With higher aspect ratios, the use of aluminum-based metallization to fill the contact openings often results in electromigration and reliability failures. To alleviate these electromigration issues and reliability failures, the semiconductor industry has evolved to using tungsten, rather than aluminum-based metallizations, for filling certain narrow, deep contact or via openings. The switch to tungsten filled contact openings takes advantage of the improved conformal, or step coverage that results from the use of a chemical vapor deposition (CVD) process. In addition, tungsten's high current carrying characteristics reduce the risk of electromigration failure.

The conventional method of forming tungsten plugs in vias includes forming an opening in a dielectric layer using conventional lithographic and etching techniques. Thereafter a titanium/titanium nitride stack is formed along the sidewalls of opening, and a tungsten plug is formed over the titanium/titanium nitride stack and filling the opening. The titanium, in most instances, is used as an adhesion layer. Conversely, the titanium nitride is used as a barrier layer to inhibit diffusion of WF₆ introduced during the deposition of the tungsten plug into the titanium layer through pinholes in the titanium nitride layer.

In certain instances, to further reduce the diffusion of WF₆ into the titanium layer, the tungsten deposition consists of a first nucleation layer formation and a second bulk tungsten formation. The nucleation layer is formed using a combination of WF₆ and SiH₄ gasses. A reduction of WF₆ by SiH₄ is a slow reaction which is well controlled. It is believed that the nucleation layer substantially retards the diffusion of the WF₆ from the bulk tungsten layer to the titanium layer. Thereafter the bulk tungsten would be deposited using the conventional WF₆ and H₂ gasses. Unfortunately, controlling the SiH₄ and WF₆ gasses during the nucleation layer formation is very critical to preventing the formation of tungsten defects in the interconnects. The presence of pinholes in the titanium nitride layer will generally allow the diffusion of WF₆ to react with titanium.

Accordingly, what is needed in the art is an interconnect structure and method of manufacture therefor that does not experience the drawbacks experienced by the prior art interconnect structures.

### SUMMARY OF THE INVENTION

To address the above-discussed deficiencies of the prior art, the present invention provides an interconnect structure, a method of manufacture therefor, and an integrated circuit including the same. The interconnect structure, among other elements, may include a tungsten nitride layer located within an opening in a dielectric layer, and a conductive plug located over the tungsten nitride layer and within the opening.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a cross-sectional view of one embodiment of a partially completed integrated circuit, including an interconnect structure, manufactured in accordance with the aspects of the present invention;

FIG. 2 illustrates a cross-sectional view of a partially completed interconnect structure manufactured in accordance with the principles of the present invention;

FIG. 3 illustrates a cross-sectional view of the partially completed interconnect structure illustrated in FIG. 2, after formation of a conductive plug over the tungsten nitride layer and within the opening;

FIG. 4 illustrates a cross-sectional view of the partially completed interconnect structure illustrated in FIG. 3, after polishing the conductive plug and then the tungsten nitride layer from the top surface of the dielectric layer, resulting in a completed interconnect structure; and

FIG. 5 illustrates an exemplary cross-sectional view of an integrated circuit (IC) incorporating interconnect structures constructed according to the principles of the present invention.

### DETAILED DESCRIPTION

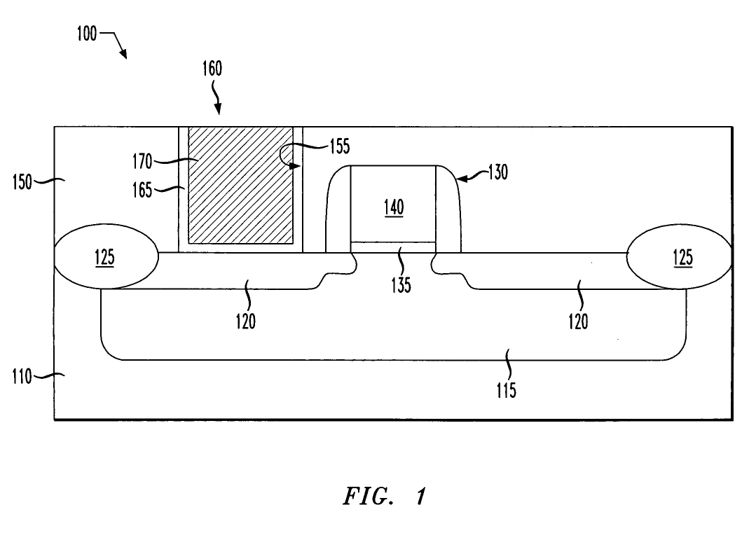

Referring initially to FIG. 1, illustrated is a cross-sectional view of one embodiment of a partially completed integrated circuit 100, including an interconnect structure 160 manufactured in accordance with the aspects of the present invention. As illustrated in FIG. 1, the partially completed integrated circuit 100 includes a semiconductor substrate 110 having a tub region 115 located therein. The tub region 115 may comprise a tub for a conventional n-channel metal oxide semiconductor (NMOS) device, or in an alternative embodiment, a tub for a conventional p-channel metal oxide semiconductor (PMOS) device. Further located within the semiconductor substrate 110 are conventional source/drain regions 120, and isolation regions 125 (e.g., field oxides). Located over the semiconductor substrate 110, in the embodiment illustrated in FIG. 1, is a gate structure 130, including a gate oxide 135 and a gate electrode 140.

Located over the gate structure 130 is a dielectric layer 150. The dielectric layer 150 may comprise any known or hereafter discovered dielectric material for use in a semiconductor device. Formed within the dielectric layer 150 is an opening 155. In one advantageous embodiment the opening 155 may be a via formed in a dielectric layer between two metal layers. However, in the particular embodiment of FIG. 1, the opening 155 is a via formed between an active device and the first metal level.

Located within the opening 155 is the previously mentioned interconnect structure 160. The interconnect structure 160, in the particular embodiment shown in FIG. 1, includes a tungsten nitride layer 165 located in the opening 155. In one advantageous embodiment, the tungsten nitride layer 165, which may optimally have a thickness of less than about 30 nm, and more particularly a thickness ranging from about 30 nm to about 5 nm, is formed directly on the sidewalls of the dielectric layer 150. For instance, in this embodiment no titanium/titanium nitride stack would be located between the tungsten nitride layer 165 and the dielectric layer 150, thus the interconnect structure 160 would be substantially free of the titanium/titanium nitride stack.

The interconnect structure 160 of FIG. 1 further includes a conductive plug 170 located over the tungsten nitride layer 165 and within the opening 155. The conductive plug 170, which may comprise any collection of one or more layers, in an exemplary embodiment is located directly on the tungsten nitride layer 165. Advantageous to the prevent invention, at least a portion of the conductive plug 170 comprises tungsten. Accordingly, in the embodiment shown and discussed with respect to FIG. 1 the tungsten nitride layer 165 and the conductive plug 170 comprise the same metal. Other conductive plug 170 materials may nonetheless be used in place of the tungsten conductive plug.

The interconnect structure 160 manufactured in accordance with the principles of the present invention provides a number of advantages over the prior art interconnect structures. Initially, since there is no titanium adhesion layer, as would be included in the prior art structures, the defects caused by the attack of the titanium layer by the WF₆ used to form the conductive plug 170 is substantially reduced, if not eliminated. Also, the removal of the titanium nitride barrier layer saves at a minimum two deposition steps per via level used. Therefore, the manufacturing throughput of the devices may be significantly increased. Additionally, the tungsten nitride layer 165 may be deposited as part of the conductive plug 170 deposition process, which again saves time and money. Similarly, the tungsten nitride layer 165 adheres well to the dielectric layer 150, as well as its electrical properties are comparable, if not superior, to those of the conventional structures.

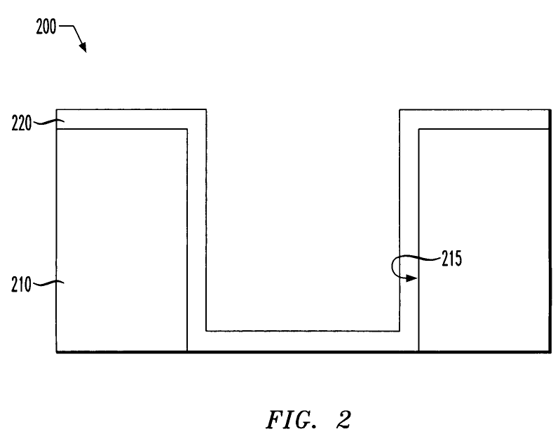

Turning now to FIGS. 2-4, illustrated are cross-sectional views of detailed manufacturing steps instructing how one might, in an advantageous embodiment, manufacture an interconnect structure similar to the interconnect structure 160 depicted in FIG. 1. FIG. 2 illustrates a cross-sectional view of a partially completed interconnect structure 200 manufactured in accordance with the principles of the present invention. The partially completed interconnect structure 200 illustrated in FIG. 2 includes a dielectric layer 210, such as an interlevel dielectric layer located over a gate structure. The dielectric layer 210 may comprise any dielectric material known by those skilled in the art, such as silicon dioxide, a low dielectric constant material, or a non-silicon dielectric material. Located within the dielectric layer 210 is an opening 215. One skilled in the art understands how to form such an opening 215, including using conventional lithographic and etching techniques.

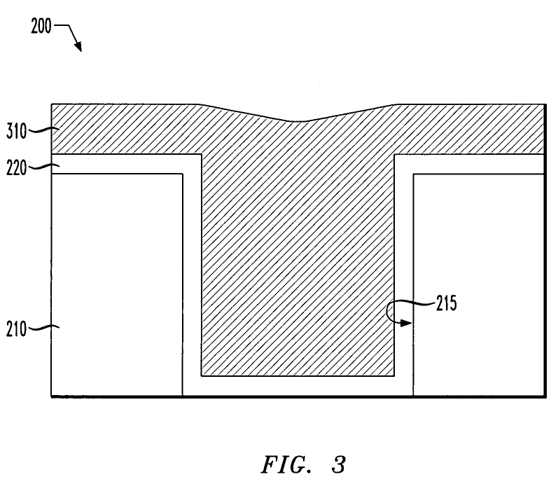

Uniquely formed within the opening 215 is a tungsten nitride layer 220. In the illustrative embodiment shown, the tungsten nitride layer 220 is also formed over an upper surface of the dielectric layer 210. The tungsten nitride layer 220 is advantageously designed to provide any necessary adhesion between the dielectric layer 210 and any subsequently formed layer. The tungsten nitride layer 220 is also advantageously designed to provide any necessary barrier properties between the dielectric layer 210 and the conductive plug 310 (FIG. 3). Accordingly, the tungsten nitride layer 220 acts as an interfacial layer, and therefore may be used to replace the titanium/titanium nitride stack, as well as possibly the nucleation layer of the prior art interconnect structures. The tungsten nitride layer 220, in one advantageous embodiment has a thickness of less than about 30 nm. In an exemplary embodiment, however, the tungsten nitride layer 220 has a thickness ranging from about 5 nm to about 30 nm. The present invention is, nonetheless, not limited to the aforementioned thicknesses.

The tungsten nitride layer 220 may be formed using various manufacturing techniques and parameters, however, in one particularly advantageous embodiment, the tungsten nitride layer 220 is formed using a conventional chemical vapor deposition (CVD) process. In one instance the tungsten nitride layer 220 may be formed using a thermal CVD process employing a mixture of WF₆ and NH₃ gases. The flow rates of the WF₆ and NH₃ gases, among others, could range from about 27 sccm to about 36 sccm and about 9 sccm to about 12 sccm, respectively. The ratio of WF₆ to NH3 gas flow is optimally maintained between 1 and 3. In one particular embodiment of the invention a small amount of SiH₄ is added to the WF₆ and NH₃ gases. The SiH₄, which might have a flow rate ranging from about 30 sccm to about 40 sccm, would advantageously be used to increase the conductivity of the tungsten nitride layer 220, if required. Additionally, the tungsten nitride layer 220 could be formed employing a deposition temperature ranging from about 350° C. to about 450° C., with an optimal temperature of about 400° C.

While certain specifics have been given with respect to forming the tungsten nitride layer 220, those skilled in the art understand that a number of different processes and conditions might be used to form the tungsten nitride layer 220. One example of an alternative manufacturing process would be to form the tungsten nitride layer 220 using an atomic layer deposition (ALD) process. It is believed that the ALD process might be extremely useful as the aspect ratio of the opening 215 increases, as is often the case with next generation devices.

Turning now to FIG. 3, illustrated is a cross-sectional view of the partially completed interconnect structure 200 illustrated in FIG. 2, after formation of a conductive plug 310 over the tungsten nitride layer 220 and within the opening 215. In the illustrative embodiment of FIG. 3 the conductive plug 310 is also formed over an upper surface of the dielectric layer 210. In an exemplary embodiment the conductive plug 310 comprises any collection of one or more layer and has a collective thickness ranging from about 300 nm to about 400 nm, depending on a width and depth of the opening 215 and the thickness of the tungsten nitride layer 220. In one particular advantageous embodiment, the thickness of the conductive plug 310 should be about 10 to about 30 times the thickness of the tungsten nitride layer 220.

In the illustrative embodiment shown in FIG. 3, the conductive plug 310 comprises tungsten, however, those skilled in the art appreciate that other similar materials that are currently known or hereafter discovered may comprise the conductive plug 310. In the particular embodiment where the conductive plug 310 comprises tungsten, the conductive plug 310 may be formed using a thermal CVD process with a gas mixture of WF₆ and H₂. The flow rates of the WF₆ and H₂ gases could range from about 350 sccm to about 450 sccm and about 6000 sccm to about 6500 sccm, respectively. Other flow rates and gasses could nonetheless be used, including the addition of Ar having a flow rate ranging from about 900 sccm to about 1100 sccm. Similarly, deposition temperatures ranging from about 350° C. to about 450° C., may be used to deposit the conductive plug 310.

In those embodiments where the conductive plug 310 is deposited using a CVD process and the conductive plug 310 comprises the same metal as the tungsten nitride layer 220, both the tungsten nitride layer 220 and the conductive plug 310 could be deposited in the same deposition chamber. In situ deposition, as this is called, can significantly decrease the amount of time, as well as expenses, associated with depositing the tungsten nitride layer 220 and the conductive plug 310. As is appreciated, a simple change to the gasses and gas flow rates would change the deposition process from that of a tungsten nitride deposition process to a tungsten deposition process.

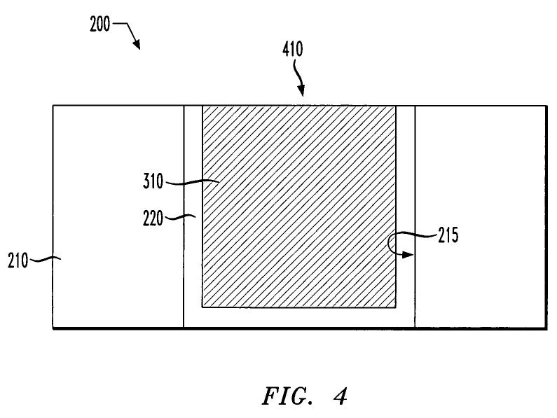

Turning to FIG. 4, illustrated is a cross-sectional view of the partially completed interconnect structure 200 illustrated in FIG. 3, after polishing the conductive plug 310 and tungsten nitride layer 220 from the top surface of the dielectric layer 210, resulting in a completed interconnect structure 410. Those skilled in the art understand the conventional processes that may be used to polish the tungsten nitride layer 220 and the conductive plug 310. In an exemplary embodiment, however, a conventional chemical mechanical planarization (CMP) process may be used.

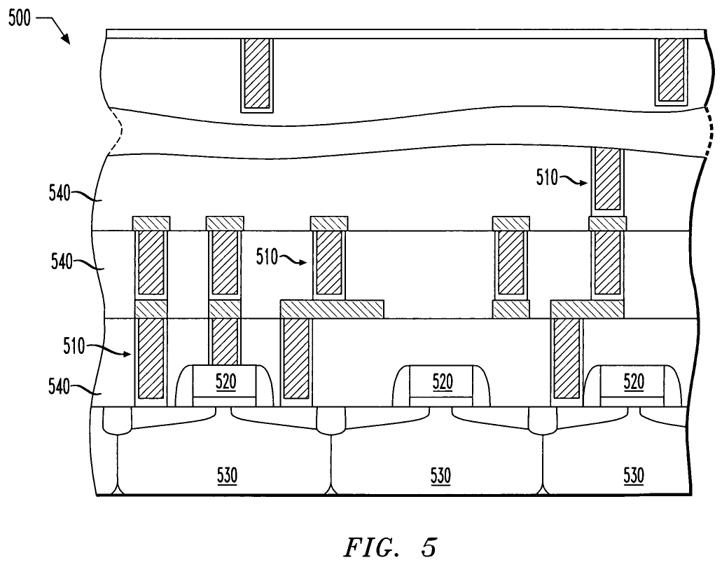

Referring finally to FIG. 5, illustrated is an exemplary cross-sectional view of an integrated circuit (IC) 500 incorporating interconnect structures 510 constructed according to the principles of the present invention. The IC 500 may include devices, such as transistors used to form CMOS devices, BiCMOS devices, Bipolar devices, as well as capacitors or other types of devices. The IC 500 may further include passive devices, such as inductors or resistors, or it may also include optical devices or optoelectronic devices. Those skilled in the art are familiar with these various types of devices and their manufacture. In the particular embodiment illustrated in FIG. 5, the IC 500 includes transistor devices 520 located over a semiconductor substrate 530. Further located over the transistor devices 520 are dielectric layers 540. As is further illustrated, interconnect structures 510 may be located within the dielectric layers 520 to interconnect various devices, thus, forming the operational integrated circuit 500.

Although the present invention has been described in detail, those skilled in the art should understand that they can make various changes, substitutions and alterations herein without departing from the spirit and scope of the invention in its broadest form.

1 . An interconnect structure, comprising:
a tungsten nitride layer located within an opening in a dielectric layer; and
a conductive plug located over the tungsten nitride layer and within the opening, the conductive plug containing tungsten substantially therethrough.

2. The interconnect structure as recited in claim 1 wherein the tungsten nitride layer is located directly on the dielectric layer.

3. The interconnect structure as recited in claim 2 wherein the conductive plug is located directly on the tungsten nitride layer.

4. The interconnect structure as recited in claim 1 wherein the tungsten nitride layer has a thickness of less than about 30 nm.

5. The interconnect structure as recited in claim 4 wherein the tungsten nitride layer has a thickness ranging from about 5 nm to about 30 nm.

6. The interconnect structure as recited in claim 1 being substantially free of a titanium/titanium nitride stack.

7. (canceled)

8-16. (canceled)

17. An integrated circuit, including:
transistors located over a semiconductor substrate;
a dielectric layer located over the transistors; and
interconnect structures located within the dielectric layer for contacting the transistors to form an operational integrated circuit, the interconnect structures including;
a tungsten nitride layer located within an opening in the dielectric layer; and
a conductive plug located over the tungsten nitride layer and within the opening, the conductive plug containing tungsten substantially therethrough.

18. The integrated circuit as recited in claim 17 wherein the tungsten nitride layer is located directly on the dielectric layer.

19. The integrated circuit as recited in claim 17 wherein the tungsten nitride layer has a thickness ranging from about 5 nm to about 30 nm.

20. The integrated circuit as recited in claim 17 being substantially free of a titanium/titanium nitride stack.

21. (canceled)
